(19) United States
(12) Patent Application Publication
(10) Pub. No.: US 2015/0060255 A1
(43) Pub. Date: Mar. 5, 2015

(54) TOUCH PANEL

(71) Applicant: Kuo-Hsing Chen, New Taipei City (TW)

(72) Inventor: Kuo-Hsing Chen, New Taipei City (TW)

(73) Assignee: WINTEK CORPORATION, Taichung City (TW)

(21) Appl. No.: 14/474,184

(22) Filed: Sep. 1, 2014

(30) Foreign Application Priority Data
Sep. 2, 2013 (TW) 102131578

(51) Int. Cl. H03K 17/96

(52) U.S. Cl. CPC H03K 17/9622; H03K 2017/9613; H03K 2217/960755
USPC 200/5 R

(57) ABSTRACT

A touch panel including a substrate and touch sensitive units is provided. Each touch sensitive unit includes a first electrode set and a second electrode set. Each first electrode set includes first electrodes separated by a first space between one another. Each second electrode set includes second electrodes separated by a second space between one another. One of a width of each second electrode and a width of each first electrode is increased along a first direction, and the other one is decreased along the first direction, wherein at least one of the second space is not aligned to at least one of the first space so that an extended trajectory of the at least one of the second space passes through one of the first electrodes. Two adjacent first electrodes are electrically independent and two adjacent second electrodes are electrically independent.

### CROSS-REFERENCE TO RELATED APPLICATION

This application claims the priority benefit of Taiwan application serial no. 102131578, filed on Sep. 2, 2013. The entirety of the above-mentioned patent application is hereby incorporated by reference herein and made a part of this specification.

### BACKGROUND OF THE INVENTION

1. Field of the Invention

The invention is related to a touch panel, and particularly to a touch panel with a multi-touch function.

2. Description of Related Art

In current information era, touch panels have been introduced to replace conventional keyboards or mice to serve as input devices of many information technology (IT) products. Among them, a touch display device capable of performing both a touch function and a display function is one of the most popular products at present.

Currently, the touch panels are roughly classified into resistive, capacitive, infrared, and ultrasonic touch panels, wherein the resistive touch panels and the capacitive touch panels are most common. When it comes to the capacitive touch panels, they are gradually favored by the market due to a multi-touch feature that provides a more user-friendly operation mode. However, for the purpose of achieving the multi-touch function, sometimes it is necessary to increase channels of a driver IC of the touch panel so as to differentiate between touch points. As a result, manufacturing cost of the touch panel is increased. Therefore, how to achieve the multi-touch function with a limited cost is worth studying in the field of touch panels.

### SUMMARY OF THE INVENTION

The invention provides a touch panel that achieves the multi-touch function by making use of arrangement manners and electrical connection manners of electrodes without a need to significantly increase the number of channels of a driver IC, and thus has an advantage of cost saving.

A touch panel of the invention includes a substrate and a plurality of touch sensitive units. The touch sensitive units are arranged in sequence on the substrate. Each touch sensitive unit includes a first electrode set and a second electrode set. The first electrode set includes a plurality of first electrodes. The first electrodes are arranged in sequence along a first direction and are separated by a first space between one another. The second electrode set is located beside the first electrode set and includes a plurality of second electrodes. The second electrodes are arranged in sequence along the first direction and are separated by a second space between one another. One of a width of each second electrode and a width of each first electrode is increased along the first direction, and the other one is decreased along the first direction, wherein at least one second space is not aligned to at least one first space so that an extended trajectory of the at least one second space passes through one of the first electrodes. Two adjacent first electrodes are electrically independent and two adjacent second electrodes are electrically independent.

In an embodiment of the invention, the width of each first electrode is increased along the first direction, and a maximum width of the n-th first electrode is smaller than a minimum width of the (n+1)-th first electrode, wherein n is a positive integer.

In an embodiment of the invention, the width of each second electrode is decreased along the first direction, and a minimum width of the m-th second electrode is larger than a maximum width of the (m+1)-th second electrode, wherein m is a positive integer.

In an embodiment of the invention, the (2n−1)-th first electrodes are electrically connected together, and the 2n-th first electrodes are electrically connected together, wherein n is a positive integer.

In an embodiment of the invention, the touch panel further includes a driver IC, a plurality of first wires, a plurality of second wires, a plurality of third wires and a plurality of fourth wires. The driver IC, the first wires, the second wires, the third wires and the fourth wires are disposed on the substrate. Each first wire is connected between the driver IC and the first electrode having a minimum width in each first electrode set. Each second wire is connected between the driver IC and the first electrode having a maximum width in each first electrode set. Each third wire is connected between the driver IC and the second electrode having a maximum width in each second electrode set. Each fourth wire is connected between the driver IC and the second electrode having a minimum width in each second electrode set.

In an embodiment of the invention, the (2m−1)-th second electrodes are electrically connected together, and the 2m-th second electrodes are electrically connected together, wherein m is a positive integer.

In an embodiment of the invention, the 2m-th second electrode in the k-th touch sensitive unit is electrically connected to the (2m−1)-th second electrode in the (k+1)-th touch sensitive unit, wherein k is a positive integer.

In an embodiment of the invention, the (2m−1)-th second electrode in the k-th touch sensitive unit is electrically connected to the 2m-th second electrode in the (k+1)-th touch sensitive unit, wherein k is a positive integer.

In an embodiment of the invention, the touch panel further includes a driver IC and a plurality of wires. The driver IC and the wires are disposed on the substrate, wherein the second electrodes in the k-th touch sensitive unit and in the (k+1)-th touch sensitive unit that are electrically connected to one another are connected to the driver IC via one of the wires.

In an embodiment of the invention, none of the second spaces is aligned to the first spaces.

In an embodiment of the invention, the touch sensitive units are arranged in sequence along a second direction, and the second direction intersects the first direction.

In an embodiment of the invention, a stair-shaped variation is exhibited in the widths of each first electrode and each second electrode.

In an embodiment of the invention, a wave-shaped variation is exhibited in the widths of each first electrode and each second electrode.

In an embodiment of the invention, a linear variation is exhibited in the widths of each first electrode and each second electrode.

In an embodiment of the invention, the substrate is any substrate in a display.

In an embodiment of the invention, the substrate is any one of a color filter substrate, an encapsulation plate and a cover lens.

In an embodiment of the invention, the substrate is any one of a glass substrate, a plastic substrate and a film substrate.

In an embodiment of the invention, the first electrodes and the second electrodes include a metal mesh consisting of a plurality of metal fine lines.

Based on the above, in each touch sensitive unit of the invention, the electrodes in the first electrode set are separated by the first spaces and the electrodes in the second electrode set are separated by the second spaces, wherein at least one second space is not aligned to the first spaces so that the extended trajectory of the at least one second space passes through one of the first electrodes. Accordingly, each first electrode corresponds to two second electrodes. When position points at which a user touches lie on the two second electrodes that correspond to the same first electrode, different touch points are differentiated according to the two different second electrodes.

In addition, two adjacent first electrodes are electrically independent and two adjacent second electrodes are electrically independent. Thus, when the user touches the two adjacent second electrodes that correspond to the same first electrode at the same time, the touch points are effectively differentiated. By making use of the arrangement manners and electrical connection manners of the electrodes, the touch panel of the invention achieves the multi-touch function without the need to significantly increase the number of channels of a driver IC, and thus has an advantage of cost saving.

To make the above features and advantages of the invention more comprehensible, embodiments accompanied with drawings are described in detail as follows.

### BRIEF DESCRIPTION OF THE DRAWINGS

FIG. 1 is a schematic view of a touch panel according to an embodiment of the invention.

FIG. 2 is a schematic view of a touch panel according to another embodiment of the invention.

FIG. 3 is a schematic view of a touch panel according to another embodiment of the invention.

FIG. 4 is a schematic view of a touch panel according to another embodiment of the invention.

FIG. 5A and FIG. 5B are embodiments of first electrodes and second electrodes in a touch sensitive unit.

### DETAILED DESCRIPTION OF DISCLOSED EMBODIMENTS

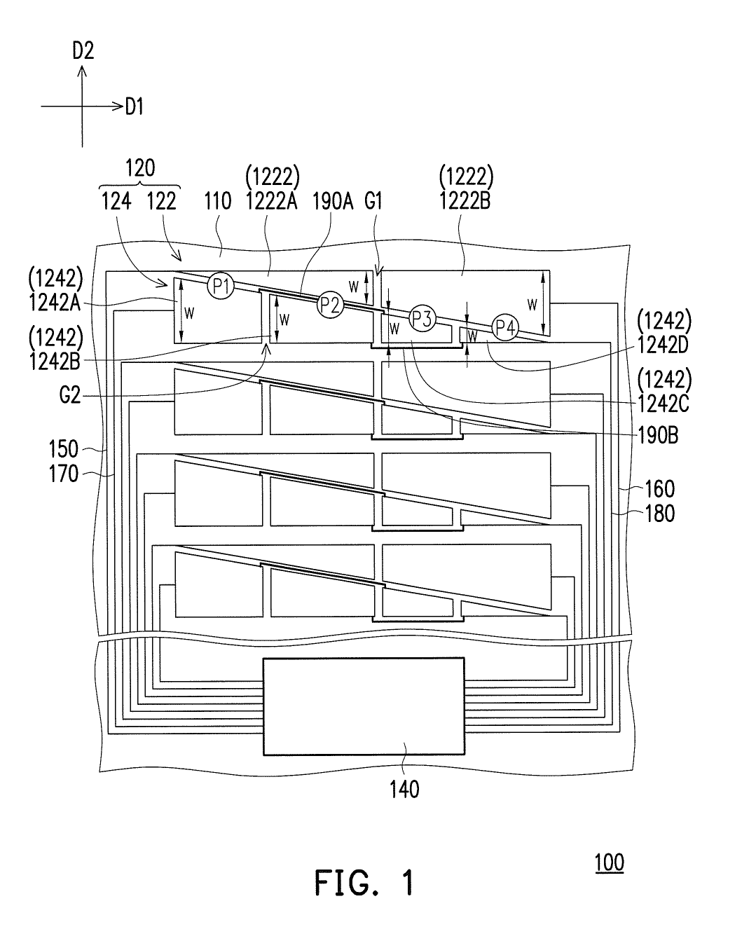

FIG. 1 is a schematic view of a touch panel according to an embodiment of the invention. Referring to FIG. 1, a touch panel 100 includes a substrate 110 and a plurality of touch sensitive units 120. The touch sensitive units 120 are arranged in sequence on the substrate 110. Each touch sensitive unit 120 includes a first electrode set 122 and a second electrode set 124. The first electrode set 122 includes a plurality of first electrodes 1222. The first electrodes 1222 are arranged in sequence along a first direction D1 and are separated by a first space G1 between one another. The second electrode set 124 is located beside the first electrode set 122 and includes a plurality of second electrodes 1242. The second electrodes 1242 are arranged in sequence along the first direction D1 and are separated by a second space G2 between one another. One of a width W of each second electrode 1242 and the width W of each first electrode 1222 is increased along the first direction D1, and the other one is decreased along the first direction D1.

It should be noted that the present embodiment illustrates an example in which each first electrode set 122 includes two first electrodes 1222 and each second electrode set 124 includes four second electrodes 1242. However, the invention is not limited thereto. The number of the first electrodes 1222 in the first electrode set 122 and the number of the second electrodes 1242 in the second electrode set 124 may be adjusted as needed. In addition, the present embodiment illustrates an example in which the width W of each first electrode 1222 is increased along the first direction D1, and the width W of each second electrode 1242 is decreased along the first direction D1. However, the invention is not limited thereto. In other embodiments, it may be that the width of the second electrode 1242 is increased along the first direction D1, and the width of the first electrode 1222 is decreased along the first direction D1. As illustrated in FIG. 1, at least one second space G2 is not aligned to at least one first space G1 so that a virtual extended trajectory of the at least one second space G2 passes through one of the first electrodes 1222.

The touch sensitive units 120 in the present embodiment are arranged in sequence along a second direction D2, and the second direction D2 intersects the first direction D1. Each touch sensitive unit 120 includes the same elements. Moreover, the elements in each touch sensitive unit 120 are arranged in the same manner and have the same electrical connection relationships. In the following, a multi-touch function of the touch panel 100 is described by illustrating a single touch sensitive unit 120 of the touch panel 100.

As illustrated in FIG. 1, in the present embodiment, the (2m−1)-th second electrodes 1242 in each second electrode set 124 are electrically connected together via a connecting wire 190A, and are connected to a driver IC 140 via a third wire 170. The 2m-th second electrodes 1242 are electrically connected together via a connecting wire 190B, and are connected to the driver IC 140 via a fourth wire 180. m is a positive integer. Meanwhile, the two first electrodes 1222 are electrically independent from each other. In other words, two adjacent first electrodes 1222 are electrically independent and two adjacent second electrodes 1242 are electrically independent.

In the touch sensitive unit 120, at least one second space G2 is not aligned to the first space G1. Accordingly, a first electrode 1222A corresponds to two different second electrodes 1242A and 1242B, and a first electrode 1222B corresponds to two different second electrodes 1242C and 1242D. When a user touches two touch points P1 and P2 at the same time, the touch points P1 and P2 are differentiated according to signals of the different second electrodes 1242A and 1242B. Or, when the user touches two touch points P3 and P4 at the same time, the touch points P3 and P4 are differentiated according to signals of the different second electrodes 1242C and 1242D.

In addition, although the second electrode 1242A and the second electrode 1242C are electrically connected to each other, when the user touches the touch points P1 and P3 at the same time, the touch points P1 and P3 are identified as different touch points according to the electrically independent first electrode 1222A and first electrode 1222B. Similarly, when the user touches the touch points P2 and P4, although the second electrode 1242B and the second electrode 1242D are electrically connected to each other, the touch points P2 and P4 are identified as different touch points according to the electrically independent first electrode 1222A and first electrode 1222B. Based on the above, the touch panel 100 in the present embodiment achieves the multi-touch function by making use of the arrangement manners and the electrical connection manners of the electrodes 1222 and 1242. In terms of the present embodiment, one touch sensitive unit 120 of the touch panel 100 is able to simultaneously sense at least the signals of the four touch points P1, P2, P3 and P4.

As illustrated in FIG. 1, the width W of each first electrode 1222 in the touch sensitive unit 120 is increased along the first direction D1, and a maximum width of the n-th first electrode 1222 is smaller than a minimum width of the (n+1)-th first electrode 1222, wherein n is a positive integer. Moreover, the width W of each second electrode 1242 is decreased along the first direction D1, and a minimum width of the m-th second electrode 1242 is larger than a maximum width of the (m+1)-th second electrode 1242, wherein m is a positive integer. In other words, an entire width of the first electrode set 122 in each touch sensitive unit 120 is progressively increased along the first direction D1, and an entire width of the second electrode set 124 is progressively decreased along the first direction D1.

The present embodiment illustrates an example in which the first electrode set 122 and the second electrode set 124 are in the shape of two complementary triangles, and hypotenuses of the two triangles are disposed opposed to each other. For example, in a single touch sensitive unit 120 of the touch panel 100, positions of the four touch points P1, P2, P3 and P4 correspond respectively to patterns of the first electrode 1222 and of the second electrode 1242 having different area ratios, thus generating different signal values. Therefore, the positions of the touch points P1, P2, P3 and P4 along the first direction D1 are determined according to size of the signal values.

In addition, in the present embodiment, the touch panel 100 further includes the driver IC 140, a plurality of first wires 150, a plurality of second wires 160, a plurality of the third wires 170 and a plurality of the fourth wires 180. The driver IC 140, the first wires 150, the second wires 160, the third wires 170 and the fourth wires 180 are disposed on the substrate 110. The first wires 150 and the second wires 160 are respectively located at two opposing sides of the first electrode set 122, wherein each first wire 150 is connected between the driver IC 140 and the first electrode 1222 having a minimum width in each first electrode set 122. Moreover, each second wire 160 is connected between the driver IC 140 and the first electrode 1222 having a maximum width in each first electrode set 122.

The third wires 170 and the fourth wires 180 are respectively located at two opposing sides of the second electrode set 124, wherein each third wire 170 is connected between the driver IC 140 and the second electrode 1242 having a maximum width in each second electrode set 124. Moreover, each fourth wire 180 is connected between the driver IC 140 and the second electrode 1242 having a minimum width in each second electrode set 124. Accordingly, the electrodes 1222 and 1242 transmit signals to the driver IC 140 via the corresponding wires 150, 160, 170 and 180. It is worth mentioning that a patterned decorative layer (not illustrated) is selectively disposed around the substrate 110 to cover the wires 150, 160, 170 and 180, and that a portion of the touch sensitive unit 120 mounts the patterned decorative layer and overlaps the same.

In a single touch sensitive unit 120 of the touch panel 100, for example, the second electrode 1242A in the second electrode set 124 is electrically connected to the second electrode 1242C, and the third wire 170 is connected between the driver IC 140 and the second electrode 1242A having the maximum width in the second electrode set 124. Accordingly, the second electrode 1242A and the second electrode 1242C are simultaneously connected to the driver IC 140 via the third wire 170. Similarly, the second electrode 1242B in the second electrode set 124 is electrically connected to the second electrode 1242D, and the fourth wire 180 is connected between the driver IC 140 and the second electrode 1242D having the minimum width in the second electrode set 124. Accordingly, the second electrode 1242B and the second electrode 1242D are simultaneously connected to the driver IC 140 via the fourth wire 180. In such electrical connection manner, the touch panel 100 in the present embodiment achieves the multi-touch function without significantly increasing the number of the wires. Accordingly, the number of channels of the driver IC 140 is decreased, thus providing the advantage of cost reduction.

In the present embodiment, materials of the first electrode 1222 and the second electrode 1242 may be transparent conductive substances, such as indium tin oxides (ITO), indium zinc oxides (IZO), aluminum zinc oxides (AZO), silver nanowires, graphene and so on. Or, the materials of the first electrode 1222 and the second electrode 1242 may be metal, or may also be a stack of metal and the transparent conductive substances, such as silver/ITO/silver. In addition, materials of the first wires 150, the second wires 160, the third wires 170 and the fourth wires 180 may be transparent conductive substances or metal. In addition, the aforementioned electrodes may be in the form of a continuous film, such as an ITO film, or in the form of a mesh (e.g. metal mesh). The mesh consists of, for example, a plurality of metal fine lines. Widths of the metal fine lines are, for example, in a range of 1 micron to 30 microns. Moreover, in the electrode in the form of a metal mesh, an opening between the fine lines is much wider than the line widths of the fine lines. As a result, a light transmittance of the metal mesh electrode reaches above 75%. In addition, the present embodiment illustrates an example in which both the first electrode 1222 and the second electrode 1242, and even the wires 150-180 as well as the connecting wires 190A and 190B are manufactured on the same surface of the substrate 110. However, the invention is not limited thereto.

The reference numerals and a part of the contents in the previous embodiment are used in the following embodiments, in which identical reference numerals indicate identical or similar components, and repeated description of the same technical contents is omitted. For a detailed description of the omitted parts, reference can be found in the previous embodiment, and no repeated description is contained in the following embodiments.

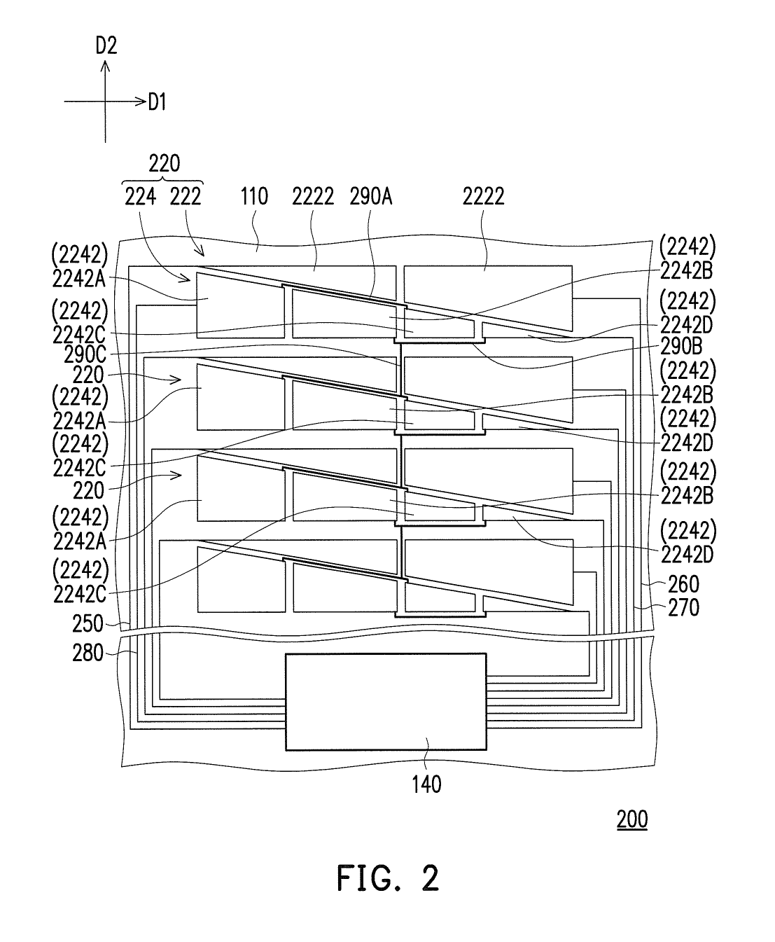

FIG. 2 is a schematic view of a touch panel according to another embodiment of the invention. The embodiment of FIG. 2 is similar to the embodiment of FIG. 1. The two embodiments differ in that in the embodiment of FIG. 2, second electrodes 2242 in two adjacent touch sensitive units 220 have an electrical connection relationship therebetween. Referring to FIG. 2, in each touch sensitive unit 220, the (2m−1)-th second electrodes 2242 are electrically connected together via a connecting wire 290A, and the 2m-th first electrodes 2222 are electrically connected together via a connecting wire 290B, wherein m is a positive integer. In addition, the 2m-th second electrode 2242 in the k-th touch sensitive unit 220 is electrically connected to the (2m−1)-th second electrode 2242 in the (k+1)-th touch sensitive unit 220 via a connecting wire 290C, wherein k is a positive integer.

Referring to FIG. 2, for example, the first second electrode 2242A in each touch sensitive unit 220 is electrically connected to the third second electrode 2242C via the connecting wire 290A, and the second electrode 2242B is electrically connected to the fourth second electrode 2242D via the connecting wire 290B. Moreover, the second second electrode 2242B and the fourth second electrode 2242D in the first touch sensitive unit 220 are electrically connected to the first second electrode 2242A and the third second electrode 2242C in the second touch sensitive unit 220 via the connecting wire 290C. Similarly, the second second electrode 2242B and the fourth second electrode 2242D in the second touch sensitive unit 220 are electrically connected to the first second electrode 2242A and the third second electrode 2242C in the third touch sensitive unit 220.

In addition, in the present embodiment, the touch panel 200 further includes the driver IC 140, a plurality of fifth wires 250, a plurality of sixth wires 260, a plurality of seventh wires 270 and an eighth wire 280. The driver IC 140, the fifth wires 250, the sixth wires 260, the seventh wires 270 and the eighth wire 280 are disposed on the substrate 110. As illustrated in FIG. 2, each fifth wire 250 is connected between the driver IC 140 and the first electrode 2222 having a minimum width in each first electrode set 222. Moreover, each sixth wire 260 is connected between the driver IC 140 and the first electrode 2222 having a maximum width in each first electrode set 222. Each seventh wire 270 is connected between the driver IC 140 and the second electrode 2242 having a minimum width in each second electrode set 224. The eighth wire 280 is connected between the driver IC 140 and the second electrode 2242 having a maximum width in one of the second electrode set 224. Accordingly, the electrodes 2222 and 2242 transmit signals to the driver IC 140 via the corresponding wires 250, 260, 270 and 280. Particularly, the second electrodes 2242 in the k-th touch sensitive unit 220 and in the (k+1)-th touch sensitive unit 220 that are electrically connected to one another are connected to the driver IC 140 simply via one of the seventh wires 270.

In the present embodiment, the second electrodes 2242 in different touch sensitive units 220 have an electrical connection relationship therebetween. Accordingly, the seventh wire 270 simultaneously connects a plurality of the second electrodes 2242 in different touch sensitive units 220 to the driver IC 140. In such electrical connection manner, the touch panel 200 in the present embodiment achieves the multi-touch function while effectively decreasing the number of the wires. Accordingly, the number of channels of the driver IC 140 is decreased, thus providing the advantage of cost reduction.

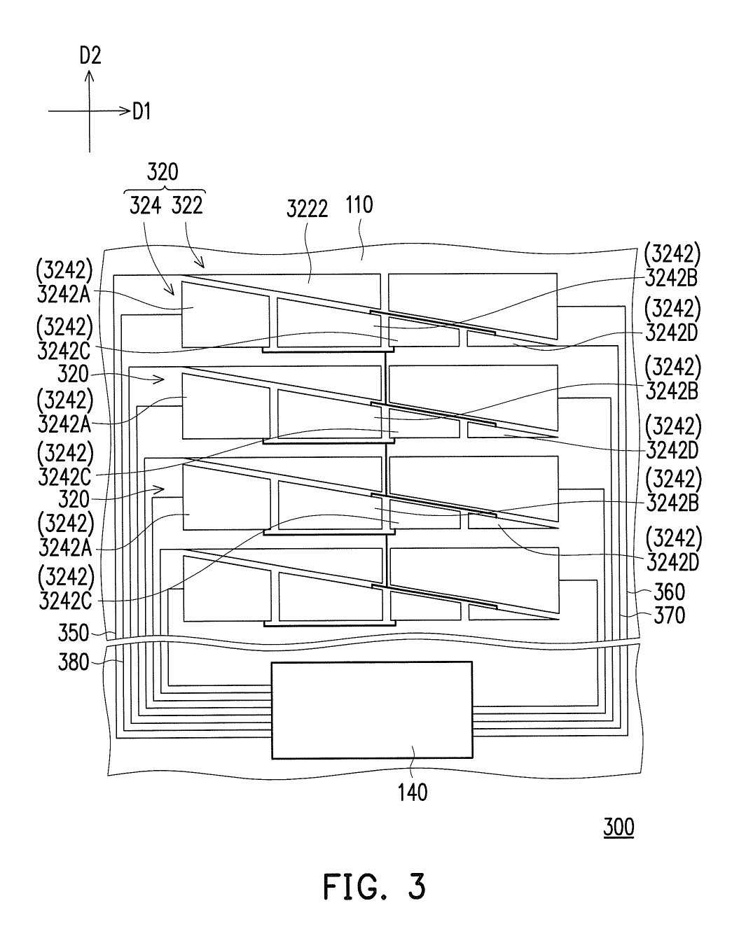

FIG. 3 is a schematic view of a touch panel according to another embodiment of the invention. The embodiment of FIG. 3 is similar to the embodiment of FIG. 2. The two embodiments differ mainly in that the (2m−1)-th second electrode 3242 in the k-th touch sensitive unit 320 is electrically connected to the 2m-th second electrode 3242 in the (k+1)-th touch sensitive unit 320, wherein k is a positive integer. In other words, in the embodiment of FIG. 2, the second second electrode 2242B and the fourth second electrode 2242D in the first touch sensitive unit 220 are electrically connected to the first second electrode 2242A and the third second electrode 2242C in the second touch sensitive unit 220. In the embodiment of FIG. 3, the first second electrode 3242A and the third second electrode 3242C in the first touch sensitive unit 320 are electrically connected to the second second electrode 3242B and the fourth second electrode 3242D in the second touch sensitive unit 320.

In addition, in the present embodiment, a touch panel 300 further includes the driver IC 140, a plurality of fifth wires 350, a plurality of sixth wires 360, a plurality of seventh wires 370 and a plurality of eighth wires 380. The driver IC 140, the fifth wires 350, the sixth wires 360, the seventh wires 370 and the eighth wires 380 are disposed on the substrate 110. As illustrated in FIG. 3, the fifth wires 350 are connected between the driver IC 140 and first electrodes 3222 having a minimum width in a first electrode set 322. Moreover, the sixth wires 360 are connected between the driver IC 140 and the first electrodes 3222 having a maximum width in the first electrode set 322. The seventh wires 370 are connected between the driver IC 140 and the second electrodes 3242 having a minimum width in a part of second electrode sets 324. The eighth wires 380 are connected between the driver IC 140 and the second electrodes 3242 having a maximum width in a part of the second electrode sets 324. Accordingly, the electrodes 3222 and 3242 transmit signals to the driver IC 140 via the corresponding wires 350, 360, 370 and 380. Particularly, the second electrodes 3242 in the k-th touch sensitive unit 320 and in the (k+1)-th touch sensitive unit 320 that are electrically connected to one another are connected to the driver IC 140 simply via one of the eighth wires 380.

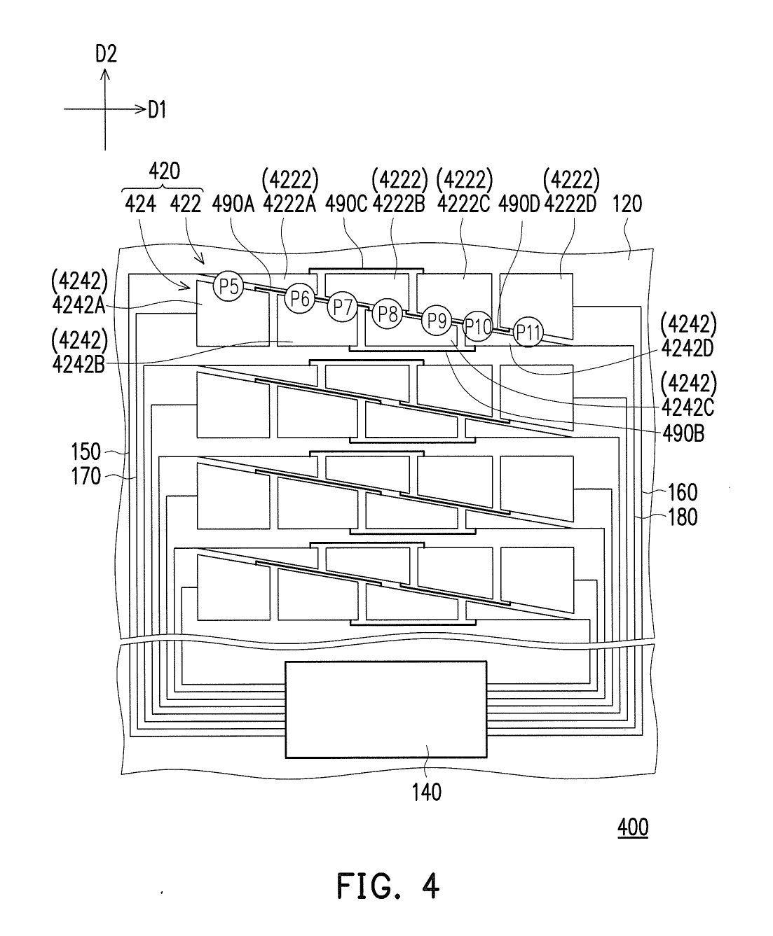

FIG. 4 is a schematic view of a touch panel according to another embodiment of the invention. The embodiment of FIG. 4 is similar to the embodiment of FIG. 1. The two embodiments differ in the electrical connection relationship between the first electrodes in the first electrode set, and relative positions of the first electrodes and the second electrodes. It should be noted that the present embodiment illustrates an example in which each first electrode set 422 includes four first electrodes 4222 and each second electrode set 424 includes four second electrodes 4242. However, the invention is not limited thereto. The number of the first electrodes 4222 in the first electrode set 422 and the number of the second electrodes 4242 in the second electrode set 424 may be adjusted as needed.

Referring to FIG. 4, in the present embodiment, none of the second spaces G2 is aligned to the first spaces G1. Moreover, the second spaces G2 and the first spaces G1 are arranged alternately. In a single touch sensitive unit 420, for example, with such arrangement, except for the last first electrode 4222D in the first electrode set 422, each first electrode 4222 faces two second electrodes 4242, while each second electrode 4242 faces two first electrodes 4222. In addition, in the present embodiment, the (2n−1)-th first electrodes 4222 in each first electrode set 422 are electrically connected together via a connecting wire 490C, and the 2n-th first electrodes 4222 are electrically connected together via a connecting wire 490D, wherein n is a positive integer. In other words, in the embodiment of FIG. 1, only the second electrodes 1242 in the second electrode set 124 have an electrical connection relationship therebetween, whereas in the present embodiment, not only the second electrodes 4242 in the second electrode set 424 are electrically connected together via connecting wires 490A and 490B, but also the first electrodes 4222 in the first electrode set 422 have an electrical connection relationship therebetween.

Please refer to FIG. 4. In the following, the multi-touch function of a touch panel 400 is described by illustrating a single touch sensitive unit 420 of the touch panel 400. When the user touches touch points P5 to P11 at the same time, at each of the touch points P5 to P11, one of the first electrodes 4222 and one of the second electrodes 4242 are respectively touched. Combinations of the first electrodes 4222 and the second electrodes 4242 touched at each of the touch points P5 to P11 are not repeated. For example, when the user touches the touch point P5, he or she touches a first electrode 4222A and a second electrode 4242A at the same time; when the user touches the touch point P6, he or she touches the first electrode 4222A and a second electrode 4242B at the same time. When the user touches the touch point P7, he or she touches a first electrode 4222B and the second electrode 4242B at the same time; when the user touches the touch point P8, he or she touches the first electrode 4222B and a second electrode 4242C at the same time. By the user touching the first electrodes 4222 and the second electrodes 4242 in different combinations when touching the touch points P5 to P11 at the same time, the touch points P5 to P11 are differentiated according to signals of the different electrodes 4222 and 4242.

In addition, two adjacent first electrodes 4222 are electrically independent and two adjacent second electrodes 4242 are electrically independent. Accordingly, when the user touches two adjacent second electrodes 4242 that correspond to the same first electrode 4222 at the same time, or touches two first electrodes 4222 that correspond to the same second electrode 4242 at the same time, the touch points are effectively differentiated. For example, when the user touches the touch point P5, he or she touches the first electrode 4222A and the second electrode 4242A at the same time; when the user touches the touch point P6, he or she touches the first electrode 4222A and the second electrode 4242B at the same time. Although the touch points P5 and P6 both correspond to the first electrode 4222A, the touch points P5 and P6 correspond to the different second electrodes 4242A and 4242B. Moreover, the second electrode 4242A is electrically independent from the second electrode 4242B. Thus, the touch points P5 and P6 are identified as different touch points. Based on the above, the touch panel 400 in the present embodiment achieves the multi-touch function. In terms of the present embodiment, one touch sensitive unit 420 of the touch panel 400 is able to simultaneously sense at least the signals of the seven touch points P5, P6, P7, P8, P9, P10 and P11.

In addition, in the present embodiment, the touch panel 400 further includes the driver IC 140, a plurality of the first wires 150, a plurality of the second wires 160, a plurality of the third wires 170 and a plurality of the fourth wires 180. The driver IC 140, the first wires 150, the second wires 160, the third wires 170 and the fourth wires 180 are disposed on the substrate 110. The wires 150-180 are arranged in the same way as in the embodiment of FIG. 1, and thus descriptions thereof are omitted. It should be noted that in the present embodiment, the first electrode 4222A is electrically connected to a first electrode 4222C. Accordingly, the first electrode 4222A and the first electrode 4222C are simultaneously connected to the driver IC 140 via the first wire 150. Similarly, the first electrode 4222B and the first electrode 4222D are simultaneously connected to the driver IC 140 via the second wire 160. In such electrical connection manner, the touch panel 400 in the present embodiment achieves the multi-touch function while effectively decreasing the number of the wires. Accordingly, the number of channels of the driver IC 140 is decreased, thus providing the advantage of cost reduction.

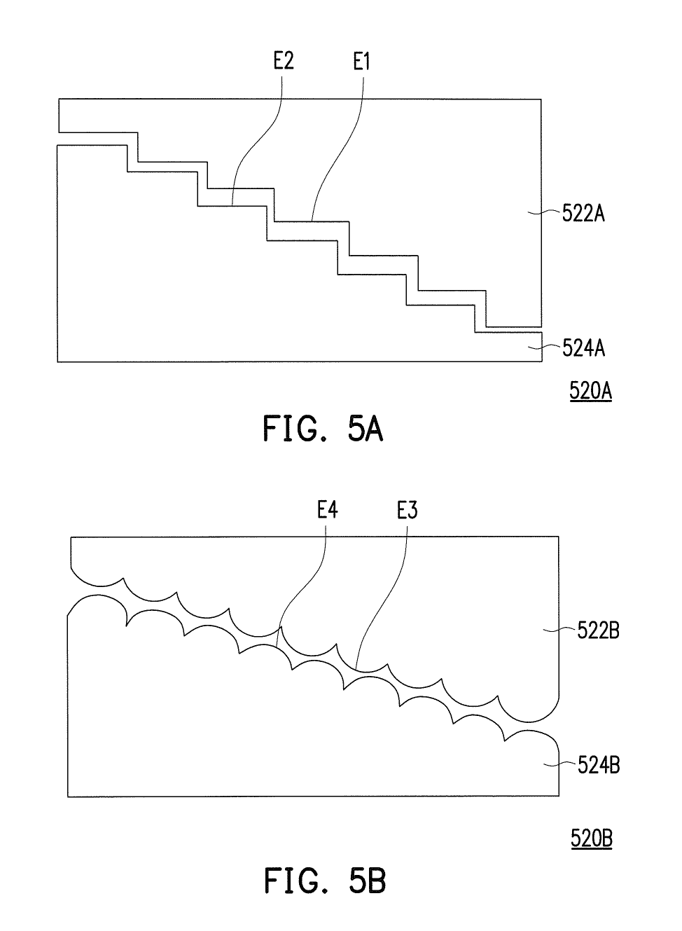

FIG. 5A and FIG. 5B are embodiments of first electrodes and second electrodes in a touch sensitive unit. The previous embodiments illustrate examples in which whole outlines of the first electrode set and the second electrode set in the touch sensitive unit are both in the form of triangles. However, the first electrode set and the second electrode set may be in other forms. As illustrated in FIG. 5A, the whole outlines of a first electrode set 522A and a second electrode set 524A in a touch sensitive unit 520A include respectively a hypotenuse E1 and a hypotenuse E2. The hypotenuse E1 and the hypotenuse E2 are disposed opposed to each other and are both zigzag-shaped. Or, as illustrated in FIG. 5B, the whole outlines of a first electrode set 522B and a second electrode set 524B in a touch sensitive unit 520B include respectively a hypotenuse E3 and a hypotenuse E4. The hypotenuse E3 and the hypotenuse E4 are disposed opposed to each other and are both wave-shaped. That is to say, in addition to the hypotenuses mentioned in the above embodiments that show a linear variation, a stair-shaped variation or a wave-shaped variation is exhibited in the widths of the first electrode sets 522A, 522B and the second electrode sets 524A, 524B. In addition, the first electrode set and the second electrode set may both have a plurality of protrusions and a plurality of recesses. Moreover, the protrusions of the first electrode set protrude into the recesses of the second electrode set, while the protrusions of the second electrode set protrude into the recesses of the first electrode set. In addition, a virtual electrode may be disposed between two adjacent touch sensitive units, between the first spaces and between the second spaces. The virtual electrodes are manufactured together with the wires and are formed on the substrate of the touch panel. The first spaces do not necessarily have the same width, and may have different widths. The same situation exists in the second spaces.

It is worth mentioning that the substrate in the aforementioned embodiments may be any substrate in a display, such as a filter substrate in a liquid crystal display or an encapsulation plate of an organic light emitting diode (OLED) display, but is not limited thereto. In addition, the substrate may be a cover lens, and a material thereof may be glass, sapphire or hard plastic. The substrate may also be a soft film material, such as a PET film or Polyimide film, but is not limited thereto.

In summary, in each touch sensitive unit of the invention, the electrodes in the first electrode set are separated by the first spaces and the electrodes in the second electrode set are separated by the second spaces, wherein at least one second space is not aligned to the first space(s) so that the extended trajectory of the at least one second space passes through one of the first electrodes. Accordingly, one first electrode corresponds to two second electrodes. When the user touches the two second electrodes that correspond to the same first electrode, the different touch points are differentiated according to the two different second electrodes.

In addition, two adjacent first electrodes are electrically independent and two adjacent second electrodes are electrically independent. Thus, when the user touches the two adjacent second electrodes that correspond to the same first electrode at the same time, or touches the two adjacent first electrodes that correspond to the same second electrode at the same time, the touch points are effectively differentiated according to the characteristic of electrical independence. By making use of the arrangement manners and the electrical connection manners of the electrodes, the touch panel of the invention achieves the multi-touch function without the need to significantly increase the number of channels of a driver IC, and thus has the advantage of cost saving. Of course, in addition to adopting the methods described in the aforementioned embodiments, a part of two adjacent first electrodes or/and two adjacent second electrodes may achieve electrical independence by an exclusive wire arranged for each electrode.

Moreover, the first electrodes in each first electrode set are electrically connected to one another, and the second electrodes in each second electrode set are electrically connected to one another. Or, the second electrodes in two adjacent touch sensitive units are electrically connected to one another. Accordingly, in the touch panel of the invention, the same wire is used to connect between a control IC and a plurality of the first electrodes that are electrically connected to one another, or the same wire is used to connect between the control IC and a plurality of the second electrodes that are electrically connected to one another. Based on the above, the touch panel of the invention achieves the multi-touch function without increasing the number of the wires, and thus has the advantage of cost saving.

Although the invention has been described with reference to the above embodiments, it will be apparent to one of ordinary skill in the art that modifications to the described embodiments may be made without departing from the spirit of the invention. Accordingly, the scope of the invention will be defined by the attached claims and not by the above detailed descriptions.

What is claimed is:

1. A touch panel, comprising:
a substrate; and
a plurality of touch sensitive units arranged on the substrate, each of the touch sensitive units comprising:
a first electrode set comprising a plurality of first electrodes arranged along a first direction, two adjacent first electrodes being separated by a first space; and
a second electrode set located beside the first electrode set and comprising a plurality of second electrodes arranged along the first direction, two adjacent second electrodes being separated by a second space, one of a width of each of the second electrodes and a width of each of the first electrodes being increased along the first direction, the other one being decreased along the first direction, wherein at least one of the second spaces is not aligned to at least one of the first spaces so that an extended trajectory of the at least one of the second spaces passes through one of the first electrodes, two adjacent first electrodes being electrically independent and two adjacent second electrodes being electrically independent.

2. The touch panel of claim 1, wherein the width of each of the first electrodes is increased along the first direction, and a maximum width of the n-th first electrode is smaller than a minimum width of the (n+1)-th first electrode, n being a positive integer.

3. The touch panel of claim 1, wherein the width of each of the second electrodes is decreased along the first direction, and a minimum width of the m-th second electrode is larger than a maximum width of the (m+1)-th second electrode, m being a positive integer.

4. The touch panel of claim 1, wherein the (2n−1)-th first electrodes are electrically connected together, and the 2n-th first electrodes are electrically connected together, n being a positive integer.

5. The touch panel of claim 1, further comprising:
a driver IC disposed on the substrate;
a plurality of first wires disposed on the substrate, each of the first wires being connected between the driver IC and the first electrode having a minimum width in each of the first electrode sets;
a plurality of second wires disposed on the substrate, each of the second wires being connected between the driver IC and the first electrode having a maximum width in each of the first electrode sets;
a plurality of third wires disposed on the substrate, each of the third wires being connected between the driver IC and the second electrode having a maximum width in each of the second electrode sets; and
a plurality of fourth wires disposed on the substrate, each of the fourth wires being connected between the driver IC and the second electrode having a minimum width in each of the second electrode sets.

6. The touch panel of claim 1, wherein the (2m−1)-th second electrodes are electrically connected together, and the 2m-th second electrodes are electrically connected together, m being a positive integer.

7. The touch panel of claim 6, wherein the 2m-th second electrode in the k-th touch sensitive unit is electrically connected to the (2m−1)-th second electrode in the (k+1)-th touch sensitive unit, k being a positive integer.

8. The touch panel of claim 7, further comprising:
a driver IC disposed on the substrate; and
a plurality of wires disposed on the substrate, wherein the second electrodes in the k-th touch sensitive unit and in the (k+1)-th touch sensitive unit that are electrically connected to one another are connected to the driver IC via one of the wires.

9. The touch panel of claim 6, wherein the (2m−1)-th second electrode in the k-th touch sensitive unit is electrically connected to the 2m-th second electrode in the (k+1)-th touch sensitive unit, k being a positive integer.

10. The touch panel of claim 9, further comprising:
a driver IC disposed on the substrate; and
a plurality of wires disposed on the substrate, wherein the second electrodes in the k-th touch sensitive unit and in the (k+1)-th touch sensitive unit that are electrically connected to one another are connected to the driver IC via one of the wires.

11. The touch panel of claim 1, wherein none of the second spaces is aligned to the first spaces.

12. The touch panel of claim 1, wherein the touch sensitive units are arranged along a second direction intersecting the first direction.

13. The touch panel of claim 1, wherein a stair-shaped variation is exhibited in the widths of each of the first electrodes and each of the second electrodes.

14. The touch panel of claim 1, wherein a wave-shaped variation is exhibited in the widths of each of the first electrodes and each of the second electrodes.

15. The touch panel of claim 1, wherein a linear variation is exhibited in the widths of each of the first electrodes and each of the second electrodes.

16. The touch panel of claim 1, wherein the substrate is any substrate in a display.

17. The touch panel of claim 1, wherein the substrate is any one of a color filter substrate, an encapsulation plate and a cover lens.

18. The touch panel of claim 1, wherein the substrate is any one of a glass substrate, a plastic substrate and a film substrate.

19. The touch panel of claim 1, wherein the first electrodes and the second electrodes comprise a metal mesh consisting of a plurality of metal fine lines.

20. The touch panel of claim 1, wherein the substrate is a polyimide film.
